(19) United States
(12) Patent Application Publication
(10) Pub. No.: US 2026/0118445 A1
(43) Pub. Date: Apr. 30, 2026

(54) METHOD AND DEVICES FOR TESTING AND MONITORING THE CONTINUITY OF A PEN CONDUCTOR FOR A THREE-PHASE TN-C-S POWER SUPPLY SYSTEM

(71) Applicant: Bender GmbH & Co. KG, Gruenberg (DE)

(72) Inventor: Dieter Hackl, Fernwald (DE)

(21) Appl. No.: 19/365,254

(22) Filed: Oct. 22, 2025

(30) Foreign Application Priority Data
Oct. 23, 2024 (DE) 10 2024 130 878.8

(51) Int. Cl. G01R 31/42; H02H 3/20

(52) U.S. Cl. CPC G01R 31/42; H02H 3/20

(57) ABSTRACT

A method and devices for testing and monitoring the continuity of a PEN conductor for a three-phase TN-C-S power supply system to which operating equipment is connected via a single or three phases. As intended by the invention, a voltage is measured for this purpose at a virtual star point set up according to the invention at operating equipment using three-phase machine terminals, and the measured star-point voltage is evaluated. Should the star-point voltage exceed a critical voltage, the operating equipment is disconnected. The invention therefore does not require a constructively difficult installation of a local reference ground. For operating equipment with single-phase machine terminals, a load voltage is measured in a first and a second load case along with a computation of a loop impedance from the voltage change and a residual-current change. The thus determined loop impedance value allows drawing a conclusion on whether a functional PEN conductor is present.

### TECHNICAL FIELD

The invention relates to methods and devices for testing and monitoring the continuity of a PEN conductor for a three-phase TN-C-S power supply system having external conductors, a neutral conductor (N conductor), a protective conductor (PE conductor) and the PEN conductor.

### BACKGROUND

In a first application, operating equipment having three-phase machine terminals (3 AC operating equipment having 3 AC machine terminals) and having a 3 AC switching element can be connected to at least one of the external conductors, the neutral conductor and the protective conductor in this TN-C-S power supply system.

Or, in a second application of the invention, operating equipment having single-phase machine terminals (AC operating equipment having AC machine terminals) is connected to one of the external conductors, the neutral conductor and the protective conductor.

The TN-C-S power supply system and the connected operating equipment each represent a prerequisite application environment for the method according to the invention and the devices implementing this method, and are not part of the invention.

Electric loads are supplied with power via power supply systems, which are designed as distribution systems in various network configurations. In this case, a power supply system having a TN-C network configuration and primarily having a TN-C-S network configuration is being viewed. In the TN-C system, a PEN conductor is both a neutral and protective conductor. In this context, the function of the neutral conductor and the protective conductor is performed by the PEN conductor throughout the entire (TN-C) installation or only in sections (TN-C-S). In the TN-C-S power supply system, the feed from the distribution network operator to a property boundary in a TN-C system with a grounded (transformer) star point is provided via a connection cable (e.g., house connection cable) having three active conductors and the PEN conductor. The PEN conductor can be grounded at several locations. In the subsequent house installation within a building, the PEN conductor is continued separately as a PE conductor and N conductor.

In the TN-C-S system, the neutral and protective conductor functions are thus implemented via the PEN conductor in a superordinate partial system (TN-C), while in subordinate partial systems (TN-S), the neutral and protective-conductor functions are designed separately in the N conductor and the PE conductor.

From the perspective of electrical safety, operator protection must be considered in the event of a fault in which the PEN conductor is interrupted at one location or is damaged to such an extent that it is no longer connected to the transformer star point with sufficiently low impedance to fulfill its function. Particular attention must be paid to fault cases in which several line sections with operating equipment are connected to each other via an interrupted or damaged PEN conductor section.

The state of the art proposes the following methods for fault detection as standard practice, e.g., in the UK standard BS 7671:
establishing a local grounding system (external reference ground), measuring the voltage between this local ground and the PEN conductor, and disconnecting the active conductors and protective grounding if this voltage exceeds 70 V within a tripping time of 5 s.
for single-phase installations, measuring the voltage between the active conductor and the N conductor and disconnecting the active conductors and protective grounding if this voltage is outside a range of 207 V to 253 V within a tripping time of 5 s.

Patent specification WO 2020/174217A1 describes an approach in which a current sensor is positioned in the current path between the protective-conductor machine terminal of a piece of operating equipment and the connection in the operating equipment between the protective conductor and touchable conductive parts (e.g., housing or protective conductor in the charging cable). In the event of a dangerously high PE conductor current, the active conductors and the inner protective conductor are disconnected within a tripping time of 5 seconds. This solution only works in an unfavorable manner if a sufficiently large fault current is already flowing, e.g., through a human body.

Patent specification EP 0 806 825 A2 provides an improved residual-current protection switch capable of detecting fault conditions relating to the protective conductor and causing an all-pole disconnection of the main circuit. In particular, fault conditions of the protective conductor are detected by using a sensor which triggers switching operations when it comes into contact with a ground close to potential. In principle, the local reference ground required by the UK standard BS 7671 is replaced here by a person standing on a ground potential with their feet, the person enabling a differential voltage measurement between the protective grounding of the installation and the ground potential of the person when touching a contact surface on the circuit breaker.

### SUMMARY

The object of the invention is therefore to present methods and devices which both allow reliable assessment of the continuity of the PEN-conductor connection in terms of quality testing, in particular reliably identifying PEN-conductor conditions, which are suitable for causing dangerous touch voltages on grounded, touchable parts of the operating equipment under unfavorable load conditions. It is not intended to install a local grounding installation. In order to ensure operator protection in the event of a fault, dangerous PEN-conductor conditions are to be identified before a dangerous fault current flows through the human body.

This objective is attained in a first application case for 3 AC operating equipment having three-phase machine terminals by measuring a star-point voltage between a virtual star point set up in the 3 AC operating equipment and the PEN conductor by means of a voltage measuring device; by evaluating the measured star-point voltage by means of an evaluation device; and by transmitting a disconnect signal to a 3 AC switching element to disconnect the external conductor, the neutral conductor, and the protective conductor in the 3 AC operating equipment should the star-point voltage exceed a critical voltage.

For the 3 AC operating equipment and for other operating equipment which has 3 AC machine terminals, a voltage measurement is performed between a virtual star point set up according to the invention and the PEN conductor using a voltage measuring device at this virtual star point on the operating equipment (star-point voltage). In this first application case, all operating equipment which has 3 AC machine terminals, even if only (capable of being) operated in single-phase mode, is referred to as 3 AC operating equipment.

The measured star-point voltage is evaluated in an evaluation device. If the star-point voltage exceeds critical voltage, the evaluation device transmits a switching signal to the 3 AC-switching element to disconnect the external conductors, the neutral conductor, and the protective conductor on this 3 AC operating equipment.

The claimed method thus does not require the constructively difficult installation of a local reference ground, but with the virtual star point set up according to the invention and the measurement of the star-point voltage with regard to the assessment of the quality of the protective properties of the PEN conductor, it delivers results comparable to those obtained when using an external, locally available reference ground.

The solution according to the invention enables a preventative disconnection of the active conductors and the protective conductor before a person can come into dangerous contact with live parts.

In a further embodiment, the star-point voltage is measured by forming the virtual star point from an interconnection of capacitors having nearly equal capacitance.

When the power supply system is subjected to a largely symmetrical load, the star-point voltage is measured at such a virtual star point, which consists of an interconnection of capacitors having nearly equal capacitance. Simulation results show that the voltage measurement in an asymmetrically loaded power supply system between the virtual star point and the PEN conductor and between the PEN conductor and ground yields almost the same value.

The switching signal is preferably transmitted by the evaluation device should a critical voltage value of 70 V be exceeded.

Should the star-point voltage between the virtual star point and the protective conductor connection exceed a voltage value of 70 V, which is considered critical based on empirical values, the active conductors (external conductor and neutral conductor) and the protective conductor on the three-phase 3 AC operating equipment or the single-phase operating equipment having 3 AC connections are disconnected within a tripping time of, for example, 5 seconds.

In simulated operating conditions with different load distributions and varying qualitative properties of the PEN conductor, the solution proposed here, which according to the invention does not require an externally provided reference ground, was able to determine sufficiently well whether the voltage between the faulty PEN conductor section and ground is below a critical voltage of, for example, 70 V.

A problematic protective grounding condition caused by an interrupted PEN conductor or one with impaired continuity is thus detected preventively, and a body current due to contact with conductive parts which may be at a dangerous voltage relative to ground is avoided.

For operating equipment having single-phase machine terminals—referred to as AC operating equipment in this second application—the object is attained: by measuring a first load voltage between the connected external conductor and the neutral conductor in a first load case by means of a voltage measuring device; by measuring a first N-conductor differential current flowing in the neutral conductor by means of a differential-current measuring device in the first load case; by measuring a second load voltage between the connected external conductor and the neutral conductor in a second load case by means of the voltage measuring device; by measuring a second N-conductor differential current flowing in the neutral conductor by means of the differential current measuring device in the second load case; by computing a loop impedance from a voltage change, formed from the first load voltage and the second load voltage, divided by a differential-current change formed from the first N-conductor differential current and the second N-conductor differential current, by means of an evaluation device; by assessing whether the loop impedance has a sufficiently small loop impedance value by means of the evaluation device; and by transmitting a switch-off signal to an AC switching element to disconnect the connected external conductor, the neutral conductor and the protective conductor on the AC-operating equipment should the loop impedance value exceed a loop impedance threshold.

For the application case of operating equipment connected via a single phase (AC operating equipment)—the operating equipment does not have any 3 AC machine terminals on which a virtual star point could be set up, as required—, the method according to the invention is based on the idea of using the load voltage dropping across a load (AC operating equipment or a measuring resistor) between the connected external conductor and the neutral conductor as well as a N-conductor differential current flowing in the neutral conductor in two load events and to estimate a loop impedance from this-viewed from the terminals of the connected load. The loop impedance value thus determined allows a conclusion on whether a functional PEN conductor is present.

In the first load case, the first load voltage and the first N-conductor differential current are measured. After a load change, the second load voltage and the second N-conductor differential current are measured under the second load. The loop impedance is computed from the voltage change, formed from the first load voltage and the second load voltage, divided by the differential-current change, formed from the first N-conductor differential current and the second N-conductor differential current.

Should this loop impedance not have a sufficiently low loop impedance value-such a sufficiently low loop impedance value can only be achieved in a parallel circuit having an existing, i.e., intact PEN conductor-, the evaluation device transmits a switching signal to the AC switching element to disconnect the connected AC operating equipment.

The method claimed for operating equipment connected via a single phase enables reliable preventative fault detection and shutdown in the event of a fault, even without the risk of dangerous body currents, compared to the state of the art.

Moreover, the differential current measuring device enables combined load-current and fault-current measurement in order to detect the loop impedance and implement an emergency shutdown in the event of a too high fault current.

In a further embodiment, the first load case is switched by opening the AC switching element of the AC operating equipment and the second load case is switched by closing the AC switching element of the AC operating equipment.

In the simplest case, the AC switching element (load switch) of the AC operating equipment connected via a single-phase is used to generate the load change by opening and closing the AC switching element, with the AC operating equipment itself acting as the load.

As an alternative to opening and closing the AC switching element of the AC operating equipment, the first and second load cases are switched by opening and closing a special measuring branch having a measuring resistor and a switch disposed between one of the external conductors and the neutral conductor.

If there are technical concerns or operational reasons for not using the AC-switching element of the AC-operating equipment directly for loop impedance measurement, the required load change can be performed by a special measuring circuit.

In this case, the first/second load voltage and the first/second N-conductor differential current are effected by opening and closing the special measuring branch by means of a switch in the measuring circuit, the measuring resistor in the measuring branch forming the load.

The other claimed structural features of the devices according to the invention each perform the corresponding method steps of the method according to the invention. Thus, the technical effects achieved with the method and the resulting advantages apply equally to the devices.

### BRIEF DESCRIPTION OF DRAWINGS

Further advantageous embodiment features are apparent from the following description and the drawings, which illustrate a preferred embodiment of the invention using exemplary simulation arrangements.

FIG. 1a, 1b show a 3 AC-TN-C-S power supply system in the fault-free case (FIG. 1a) and when the PEN conductor is interrupted (FIG. 1b).

FIG. 2 shows the 3 AC-TN-C-S power supply system when the PEN conductor is interrupted and the AC-operating equipment is inactive upon contact with a grounded enclosure which assumes a dangerous voltage to ground.

FIG. 3a, 3b show the 3 AC-TN-C-S power supply system having a virtual star point set up according to the invention for 3 AC operating equipment having three-phase machine terminals when the PEN conductor is interrupted and when 3 AC operating equipment is active (FIG. 3a) and inactive (FIG. 3b).

FIG. 4a, 4b show the 3 AC-TN-C-S power supply system with a load change according to the invention for AC operating equipment having single-phase machine terminals when the PEN conductor is interrupted in the first load case (FIG. 4a) and in the second load case (FIG. 4b).

FIG. 5 shows the 3 AC-TN-C-S power supply system with a load change according to the invention for AC operating equipment having single-phase machine terminals when the PEN conductor is impaired and upon physical contact.

FIG. 6a, 6b show the 3 AC-TN-C-S power supply system with a load change according to the invention and a measuring branch for AC operating equipment having single-phase machine terminals with intact PEN conductor in the first load case (FIG. 6a) and in the second load case (FIG. 6b).

### DETAILED DESCRIPTION

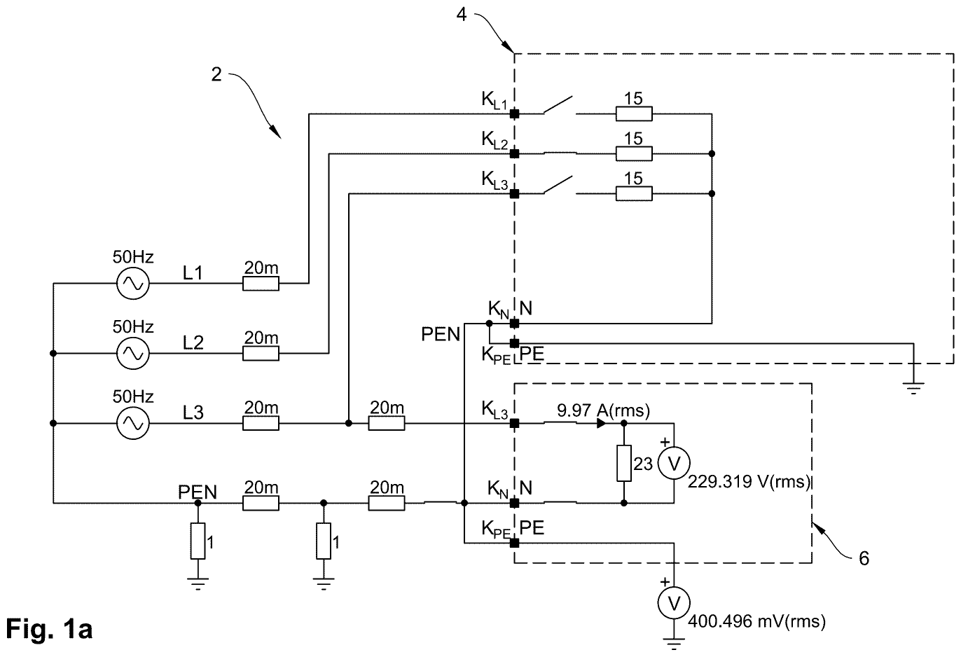

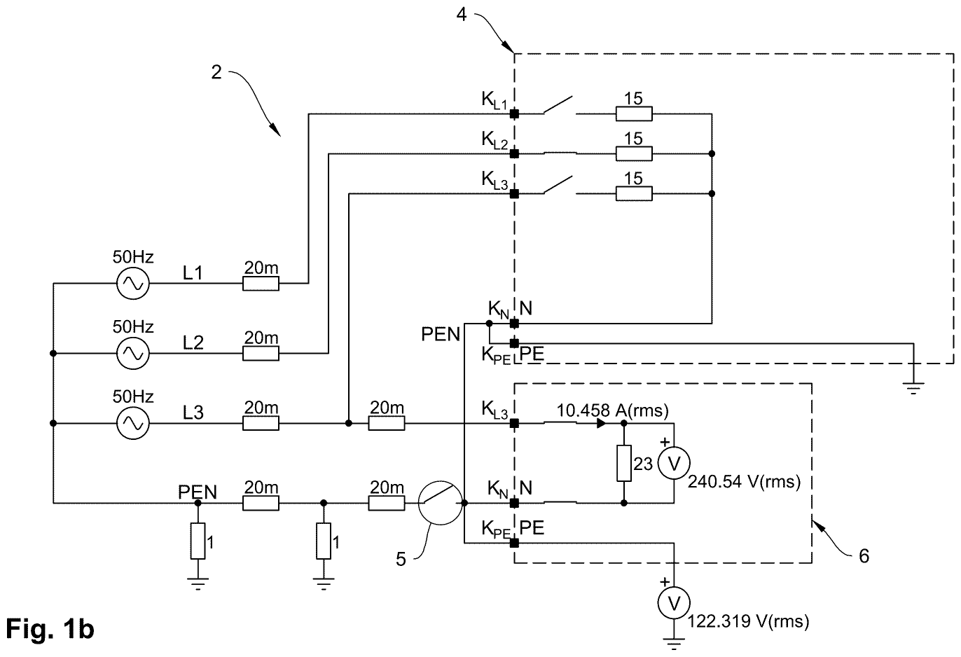

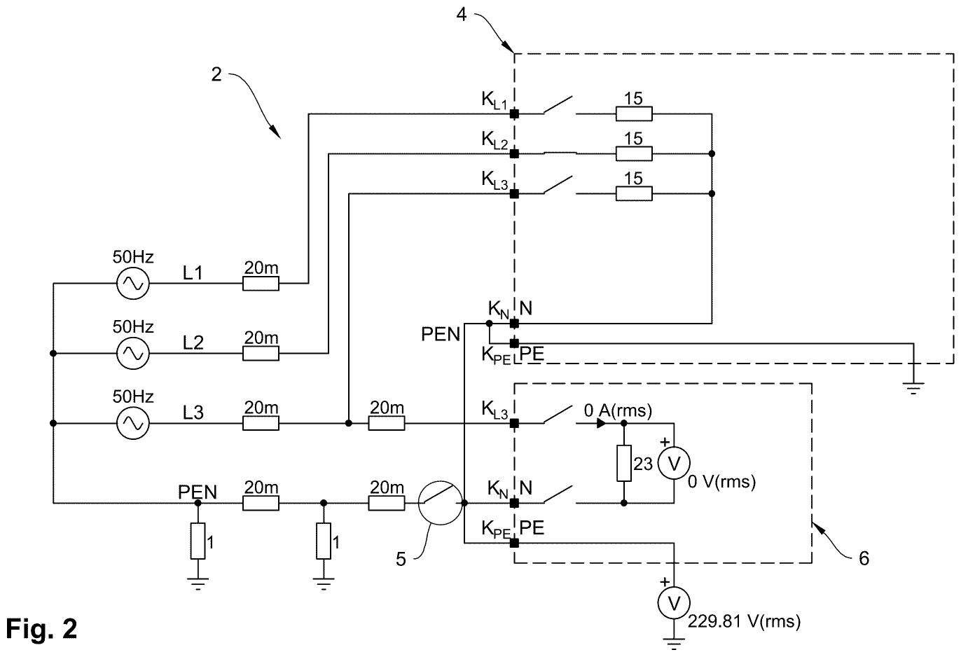

FIGS. 1a, 1b, and 2 show simulation arrangements with results of the current and voltage distribution for a 3 AC-TN-C-S power supply system 2, to which 3 AC operating equipment 4 and AC operating equipment 6 are connected as examples. The simulation arrangements shown in FIGS. 1a, 1b, and 2 represent assumed application environments for the method and device according to the invention for testing and monitoring the continuity of a PEN conductor PEN.

FIG. 1a shows a three-phase (3 AC) TN-C-S power supply system 2 in the fault-free case. FIG. 1b shows the TN-C-S power supply system 2 in the fault case with an interruption 5 of the PEN conductor PEN.

The TN-C-S power supply system is designed as a TN-C system having a grounded transformer star point at the supply point. In this partial system, the PEN conductor PEN is both the neutral conductor N and the protective conductor PE. In the subsequent TN-S system, the PEN conductor PEN is divided into the neutral conductor N and the protective conductor PE—in the simulation arrangement, the separation is carried out at the respective operating equipment 4, 6.

The 3 AC operating equipment 4 has 3 AC machine terminal K_{L1}, K_{L2}, K_{L3}, K_{N}, K_{PE} in the form of a three-phase 3 AC machine terminal block, the 3 AC machine terminals being able to be connected to the external conductors L1, L2, L3, the neutral conductor N and the protective conductor PE. For simplicity, only the external conductor (phase) L2 is connected in the simulation, so that only the load connected to it is effective.

The AC-operating equipment 6 has AC-machine terminals K_{L3}, K_{N}, K_{PE} in the form of a single-phase AC-machine terminals block and is connected to the external conductor L3, the neutral conductor N, and the protective conductor PE. The body of this AC operating equipment 6 could be, for example, the body of an electric vehicle whose energy storage device is being charged at a charging station.

If the body of the electric vehicle is touched by a person, only harmless low voltages (400 mV) are to be expected in a fault-free condition (FIG. 1a); however, in a faulty state with an interruption 5 (FIG. 1b) of the PEN conductor PEN, dangerously high voltages (122 V) to ground can occur, which can cause physiological effects hazardous to human health, including cardiac arrest.

The simulations show that an interruption 5 of the PEN conductor PEN can lead to unfavorable load distributions in those parts of the system which are also connected to the line section of the interrupted PEN conductor PEN, which can result in a dangerous voltage (122 V, FIG. 1b) to ground on touchable conductive parts which are protectively grounded, while the voltage (240 V) between the external conductor L3 and the N conductor N at the AC operating equipment 6 is still within the standard range of 207 V to 253 V.

FIG. 2 shows the 3 AC-TN-C-S power supply system 2 with interruption 5 of the PEN conductor PEN and inactive AC operating equipment 6 (charging station) when touching a protectively grounded housing which assumes a dangerous voltage to ground.

The simulations show that, in the worst-case scenario, an interruption 5 of the PEN conductor PEN can result in a dangerous voltage (229 V) occurring on touchable conductive parts connected to the PEN conductor PEN, even when the AC operating equipment 6 (charging station) is inactive (disconnected).

Since charging station 6 is already switched off in this case, additional protection from a residual current device (RCD) is not necessary in this case. A residual current device (RCD) would disconnect the active conductors L3 and N as intended and, in unfavorable cases, could even increase the touch voltage due to this disconnection, as no current can then flow through the charging station 6. The dangerous physiological effects on the human body would be intensified if a vehicle body were touched which is connected to the PEN conductor PEN when the charging plug is inserted even when inactive.

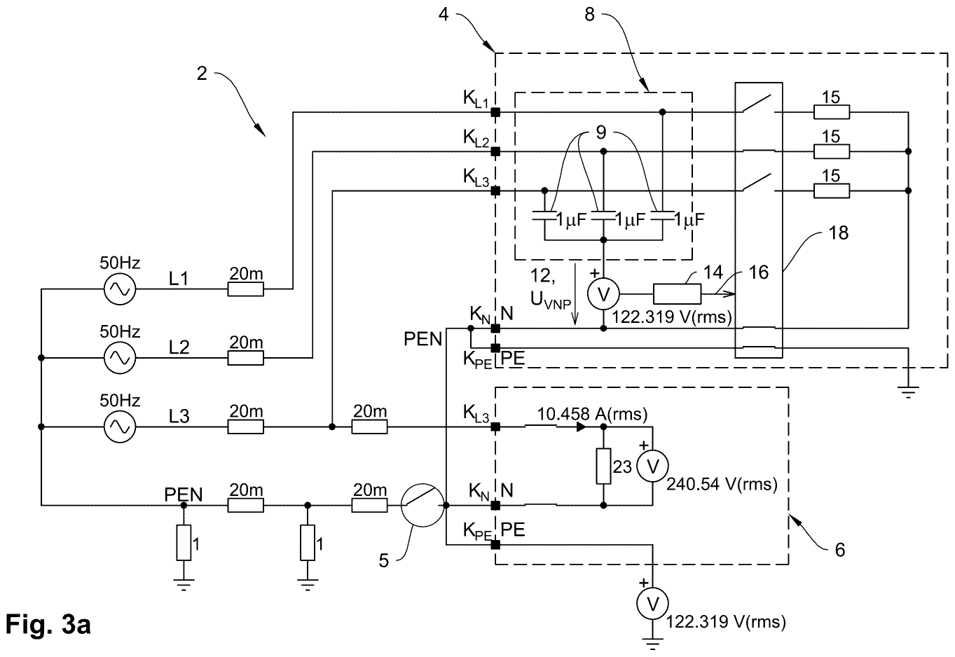

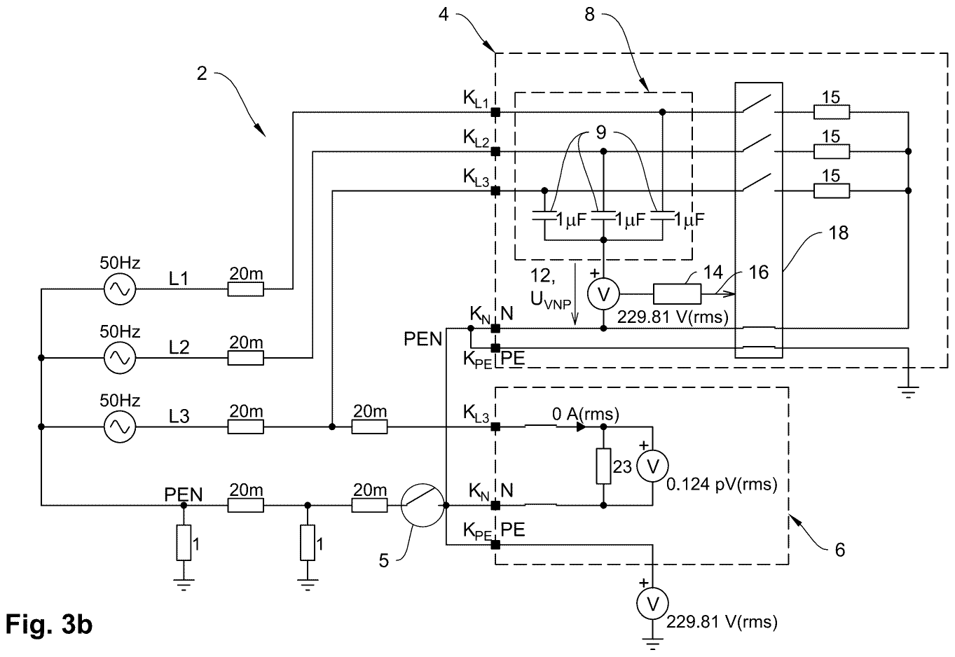

FIGS. 3a and 3b show the 3 AC-TN-C-S power supply system 2 having a virtual star point 8 set up according to the invention for 3 AC operating equipment 4 having three-phase machine terminals K_{L1}, K_{L2}, K_{L3}, K_{N}, K_{PE} in the event of an interruption 5 of the PEN conductor PEN and with active (FIG. 3a) and inactive (FIG. 3b) 3 AC operating equipment 4.

The virtual star point 8 is formed from an interconnection of capacitors 9 which have nearly equal capacity. With the installation of the virtual star point 8, the cumbersome construction of a local grounding system (external reference ground) can be dispensed with.

The simulations show that the measurement result for the star-point voltage U_{VNP} measured by means of a voltage measuring device 12 between the virtual star point 8 set up at the 3 AC operating equipment 4 and the PEN conductor PEN is significantly above a critical voltage Uₗᵢₘ of 70 V, both when the 3 AC operating equipment 4 is active and when it is inactive.

The evaluation device 14 detects the star-point voltage U_{VNP}, evaluates it, and, if the critical voltage Uₗᵢₘ is exceeded, transmits a shutdown signal 16 to a 3 AC switching element 18 to disconnect the external conductors L1, L2, L3, the neutral conductor N, and the protective conductor PE on the 3 AC operating equipment 4.

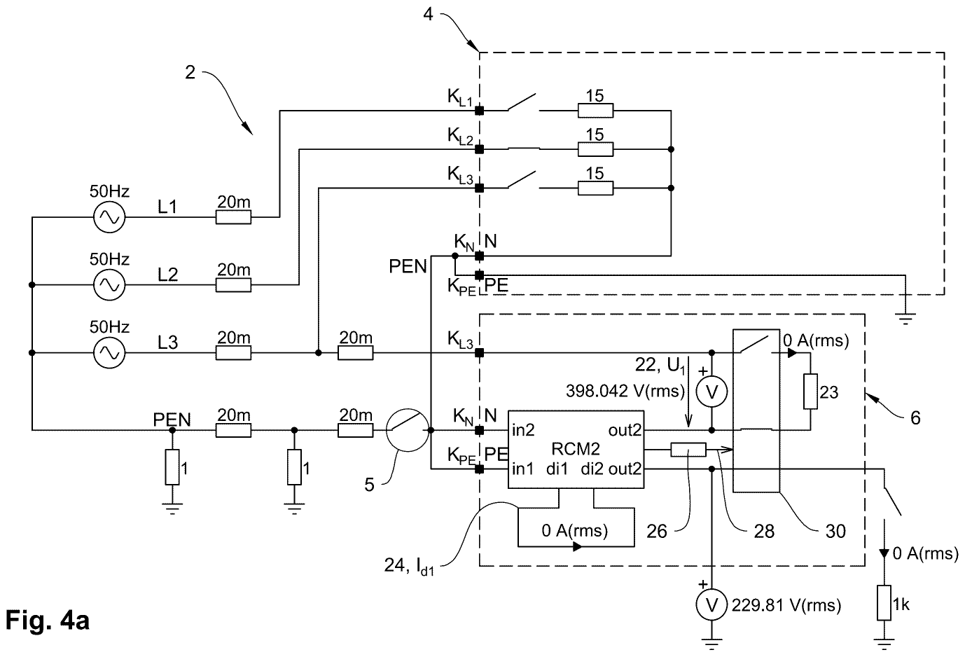

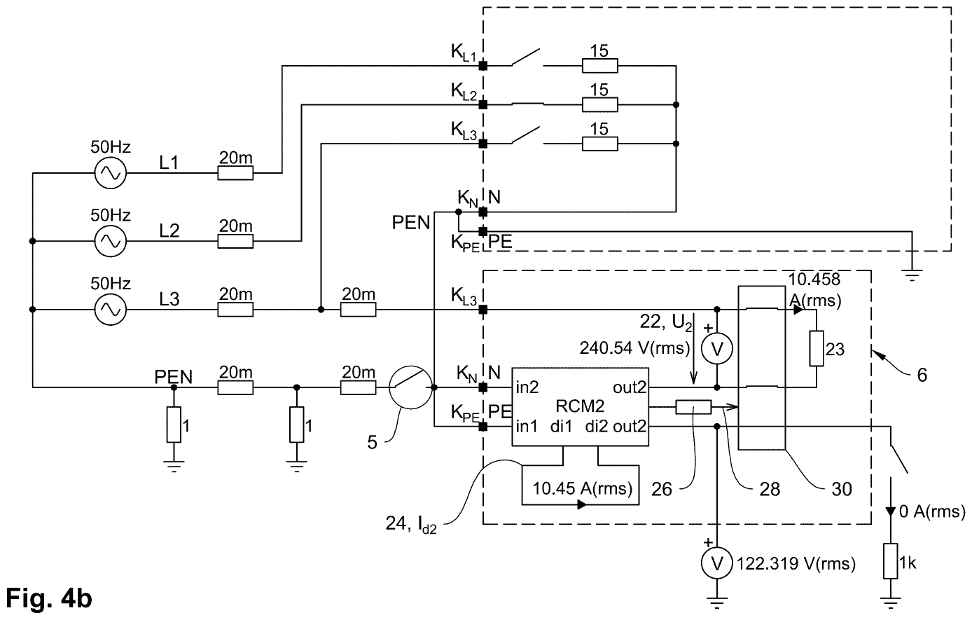

FIGS. 4a and 4b show a solution according to the invention for AC operating equipment 6 having single-phase AC machine terminals K_{L3}, K_{N}, K_{PE} in the event of an interruption 5 of the PEN conductor PEN.

According to the invention, a load change takes place between a first load case (FIG. 4a) and a second load case (FIG. 4b).

In the first load case, the AC switching element 30 on the AC operating equipment 6 is open. Therefore, no load current flows through the AC operating equipment 6 and a first load voltage U₁ (398 V) is measured by means of the voltage measuring device 22. The differential-current measuring device 24 indicates that no first N-conductor differential current I_{d1} (0 A) is flowing.

After closing the AC switching element 30 on the AC operating equipment 6, the second load voltage U₂ (240 V) and the second N-conductor differential current I_{d2} (10.5 A) are established in the second load case.

The loop impedance Z_{Loop} (loop impedance value) can be estimated from the voltage change ΔU and the differential-current change ΔI which result from the load change:

$${Z}_{Loop} = \frac{Δ U}{Δ I} = \frac{398 V - 240.5 V}{10.5 A} \approx 15 Ω$$

Since the PEN conductor PEN in the event shown was separated by the interruption 5 with high impedance, the loop impedance Z_{Loop} is formed only by the load of the 3 AC operating equipment 4 which is connected to the external conductor L2 and is connected to the shared part of the interrupted PEN conductor PEN. From this, it can be concluded that there is no other parallel low-impedance connection through a functional PEN conductor PEN, thus indicating an interruption 5 of the PEN conductor PEN.

The evaluation device 26 performs this evaluation and transmits a shutdown signal 28 to the AC switching element 30 to disconnect the connected external conductor L3, the neutral conductor N, and the protective conductor PE on the AC-operating equipment 6.

This allows a robust assessment of a critical condition of the PEN conductor PEN to be made and the disconnection of the AC operating equipment 6 can be effected, for example, within a tripping time of 5 s.

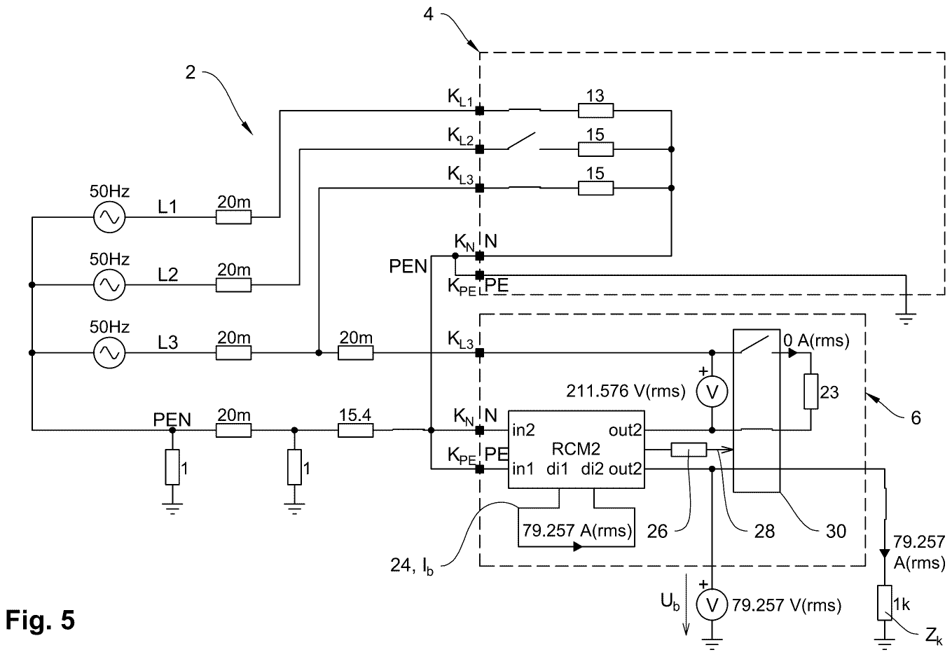

FIG. 5 shows the 3 AC-TN-C-S power supply system 2 with a load change according to the invention for AC operating equipment 6 having single-phase machine terminals K_{L3}, K_{N}, K_{PE} when the PEN conductor PEN is impaired and upon physical contact.

The human body is represented by a body impedance Zₖ (1 kΩ) and the PEN conductor PEN is not completely interrupted here, but has an impermissibly high value of 15.4Ω.

When the single-phase operating equipment 6 is inactive, i.e., when the AC switching element 30 is open, the fault current can be determined by means of the differential-current measuring device 24 via a person in the event of contact (contact current I_{b}). Here, too, a disconnection of the active conductors and the protective ground can be achieved within a tripping time of 5 s, for example.

The voltage between the external conductor L3 and the neutral conductor N is in the range of 207 V to 253 V. The touch voltage U_{b} on the protective ground of AC operating equipment 6 to ground is greater than 70 V.

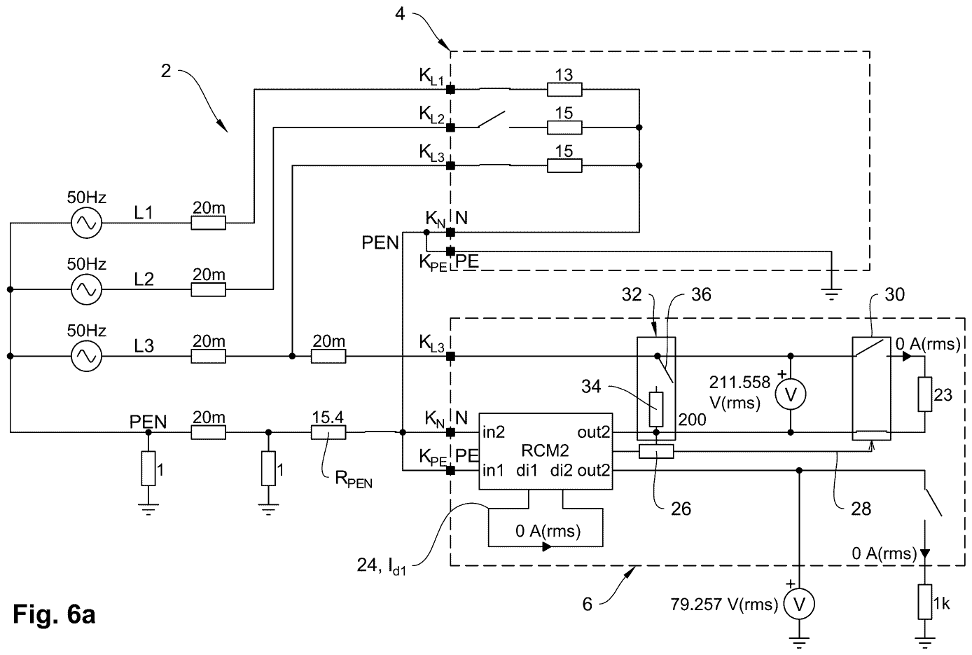

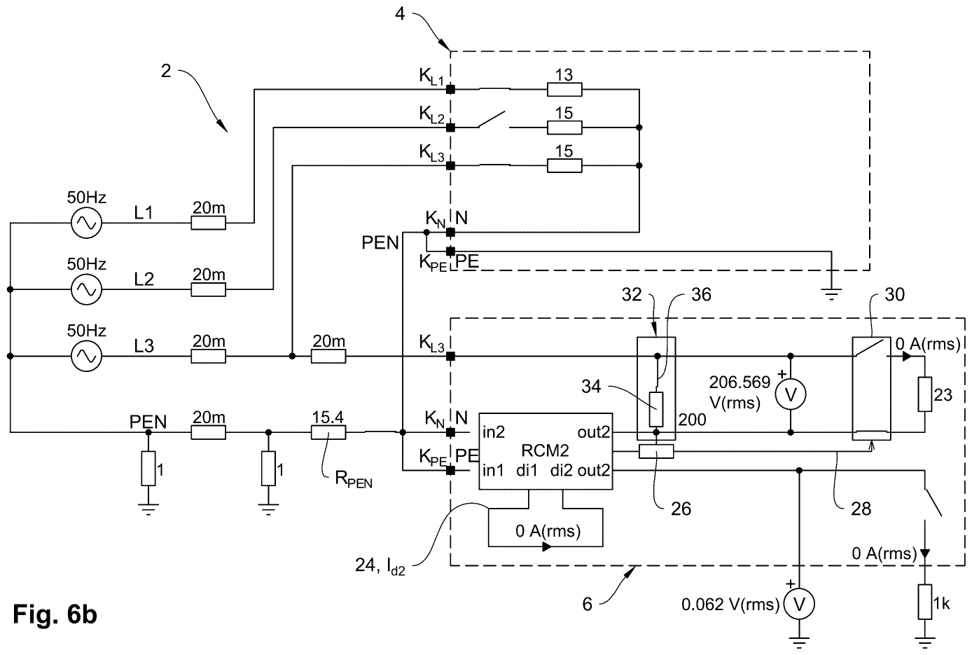

FIGS. 6a and 6b show the 3 AC-TN-C-S power supply system 2 with a load change and a measuring branch 32 according to the invention for AC operating equipment 6 with single-phase machine terminals K_{L3}, K_{N}, K_{PE} when the PEN conductor PEN is intact in the first load case (FIG. 6a) and in the second load case (FIG. 6b).

In contrast to the illustrations in FIG. 4a, 4b, which document an interruption of the PEN conductor PEN, the PEN conductor PEN in this simulation shows no interruption in order to prove its functionality.

The load change is produced by opening and closing a switch 36 in a special measuring branch 32 disposed between one of the external conductors L3 and the neutral conductor N, with the load being formed by a measuring resistor 34.

In the first load case (FIG. 6a) with the switch 36 open, the first load voltage U₁ (211.6 V) is established, and in the second load case (FIG. 6b), the second load voltage U₂ (206.6 V) is established between the active conductor L3 and the neutral conductor N. The detected first and second N-conductor differential currents I_{d1} and Laz are 0 A and 1.03 A, respectively. The loop impedance Z_{Loop} (loop impedance value) is estimated as follows:

$${Z}_{Loop} = \frac{Δ U}{Δ I} = \frac{211.6 V - 206.6 V}{1.03 A} \approx 4.85 Ω$$

Since the PEN conductor PEN in the case shown was simulated with an (increased) PEN-to-conductor resistance value R_{PEN} (15.4Ω), the loop impedance Z_{Loop} is formed by the parallel connection of the loads on the external conductors L1 and L3 of the 3 AC operating equipment 4 and the PEN conductor resistance.

The following value can be expected based on the following computation:

$${Z}_{Loop} = \frac{1}{\frac{1}{13 Ω} + \frac{1}{15 Ω} + \frac{1}{15.4 Ω}} \approx 4.83 Ω$$

For installations fused with 16 A, the loop impedance Z_{Loop} should be below approx. 2Ω.

1. A method for testing and monitoring the continuity of a PEN conductor (PEN) for a three-phase TN-C-S power supply system (2) which has external conductors (L1, L2, L3), a neutral conductor (N), a protective ground (PE) and the PEN conductor (PEN) and to which 3 AC operating equipment (4) having three-phase 3 AC machine terminals (K_{L1}, K_{L2}, K_{L3}, K_{N}, K_{PE}) is connected, the 3 AC operating equipment (4) being connected to at least one of the external conductors (L1, L2, L3), the neutral conductors (N) and the protective conductor (PE), the method comprising the following steps:
measuring a star-point voltage (U_{VNP}) between a virtual star point (8) set up on the 3 AC operating equipment (4) and the PEN conductor (PEN) by means of a voltage measuring device (12), evaluating the measured star-point voltage (U_{VNP}) by means of an evaluation device (14) and transmitting a disconnect signal (16) to a 3 AC switching element (18) to disconnect the external conductors (L1, L2, L3), the neutral conductor (N) and the protective conductor (PE) on the 3 AC operating equipment (4) should the star-point voltage (U_{VNP}) exceed critical voltage (Uₗᵢₘ).

2. The method according to claim 1,
wherein the star-point voltage (U_{VNP}) is measured by the virtual star point (8) being formed from an interconnection of capacitors (9) having nearly equal capacitance.

3. The method according to claim 1,
wherein the disconnect signal is transmitted by the evaluation device (14) should a critical voltage (Uₗᵢₘ) of 70 V be exceeded.

4. A method for testing and monitoring the continuity of a PEN conductor (PEN) for a three-phase TN-C-S power supply system (2) which has external conductors (L1, L2, L3), a neutral conductor (N), a protective conductor (PE) and the PEN conductor (PEN) and to which AC operating equipment (6) having single-phase AC machine terminals (K_{L3}, K_{N}, K_{PE}) is connected, the AC operating equipment (6) being connected to one of the external conductors (L3), the neutral conductor (N) and the protective conductor (PE), the method comprising the following steps:
measuring a first load voltage (U₁) between the connected external conductor (L3) and the neutral conductor (N) in a first load case by means of a voltage measuring device (22),
measuring a first N-conductor differential current (I_{d1}) flowing in the neutral conductor (N) by means of a differential current measuring device (24) in the first load case,
measuring a second load voltage (U₂) between the connected external conductor (L3) and the neutral conductor (N) by means of the voltage measuring device (22) in a second load case,
measuring a second N-conductor differential current (I_{d2}) flowing in the neutral conductor (N) by means of the differential current measuring device (24) in the second load case,
computing a loop impedance (Z_{Loop}) from a voltage change (ΔU), realized from the first load voltage (U₁) and the second load voltage (U₂), divided by a residual-current change (ΔI), realized from the first N-conductor differential current (I_{d1}) and the second N-conductor differential current (I_{d2}), by means of an evaluation device (26),
evaluating whether the loop impedance has a sufficiently small loop impedance value by means of the evaluation device (26) and transmitting a disconnect signal (28) to an AC switching element (30) to disconnect the connected external conductor (L3), the neutral conductor (N) and the protective conductor (PE) on the AC operating equipment (6) should the loop impedance value exceed a loop impedance threshold (Zₗᵢₘ).

5. The method according to claim 4,
wherein
the first load case is switched by opening the AC switching element (30) of the AC operating equipment (6), and the second load case is switched by closing the AC switching element (30) of the AC operating equipment (6).

6. The method according to claim 4,
wherein
the first and the second load case are switched by opening and closing a special measuring branch (32) which is disposed between one of the external conductors (L3) and the neutral conductor (N) and has a measuring resistance (34) and a switch (36).

7. The method according to claim 4,
wherein
a touch current is measured at the inactive AC operating equipment (6).

8. A device for testing and monitoring the continuity of a PEN conductor (PEN) for a three-phase TN-C-S power supply system (2) which has external conductors (L1, L2, L3), a neutral conductor (N), a protective conductor (PE) and the PEN conductor (PEN) and to which 3 AC operating equipment (4) is connected via three phases and 3 AC machine terminals (K_{L1}, K_{L2}, K_{L3}, K_{N}, K_{PE}) to the external conductors (L1, L2, L3), the neutral conductor (N) and the protective conductor (PE), with a 3 AC switching element (18) to disconnect the 3 AC operating equipment (4),
wherein
a virtual star point (8) set up at the 3 AC operating equipment (4), a voltage measuring device (12) for measuring a star-point voltage (U_{VNP}) between the virtual star point and the PEN conductor (PEN), an evaluation device (14), which is configured to evaluate the measured star-point voltage (U_{VNP}) and for transmitting a disconnect signal (16) to the 3 AC switching element (18) to disconnect the external conductor (L1, L2, L3), the neutral conductor (N) and the protective conductor (PE) on the 3 AC operating equipment (4) should the star-point voltage (U_{VNP}) exceed a critical voltage (Uₗᵢₘ).

9. The device according to claim 8,
wherein
the virtual star point (8) is formed from an interconnection of capacitors (9) having nearly equal capacitance.

10. The device according to claim 8,
wherein
the critical voltage (Uₗᵢₘ) is 70 V when the disconnect signal is transmitted.

11. A device for testing and monitoring the continuity of a PEN conductor (PEN) for a three-phase TN-C-S power supply system (2) which has external conductors (L1, L2, L3), a neutral conductor (N), a protective conductor (PE) and the PEN conductor (PEN) and to which AC operating equipment (6) is connected via one phase and AC machine terminals (K_{L3}, K_{N}, K_{PE}) to one of the external conductors (L3), the neutral conductor (N) and the protective conductor (PE), with an AC switching element (30) to disconnect the AC operating equipment (6),
wherein
a voltage measuring device for measuring a first and a second load voltage (U₁, U₂) between the connected external conductor (L3) and the neutral conductor (N) in a first and a second load case, a residual-current measuring device (24) for measuring a first and a second N-conductor differential current (I_{d1}, I_{d2}) flowing in the neutral conductor (N) in the first and the second load case, an evaluation device (26) which is configured to compute a loop impedance (Z_{Loop}) from a voltage change (ΔU), formed from the first load voltage (U₁) and the second load voltage (U₂) divided by a differential-current change (ΔI), formed from the first N-conductor differential current (I_{d1}) and the second N-conductor differential current (I_{d2}) and to transmit a disconnect signal (28) to the AC switching element (30) to disconnect the connected external conductor (L3), the neutral conductor (N) and the protective conductor (PE) at the AC operating equipment (6) should the loop impedance value exceed a loop impedance threshold (Zₗᵢₘ).

12. The device according to claim 11,
wherein
a special measuring branch (32) which is disposed between one of the external conductors (L3) and the neutral conductor (N) and has a measuring resistance (34) and a switch (36) for switching the first and the second load case by opening and closing the measuring branch (32).

13. The device according to claim 11,
wherein
the residual-current measuring device (24) is configured to measure a touch current (I_{b}) on the inactive AC operating equipment (6).
